(19) United States
(12) Patent Application Publication
(10) Pub. No.: US 2021/0380612 A1
(43) Pub. Date: Dec. 9, 2021

(54) PHOTORESIST COMPOSITIONS

(71) Applicant: Samsung Electronics Co., Ltd., Suwon-si (KR)

(72) Inventors: Chawon Koh, Yongin-si (KR); Moonil Jung, Suwon-si (KR); Tsunehiro Nishi, Seongnam-si (KR); Kunwoo Baek, Suwon-si (KR); Mijeong Song, Suwon-si (KR); Jaehyun Kim, Suwon-si (KR); Seung Han, Suwon-si (KR)

(73) Assignees: Samsung Electronics Co., Ltd., Suwon-si (KR); Samsung SDI Co., Ltd., Yongin-si (KR)

(21) Appl. No.: 17/144,242

(22) Filed: Jan. 8, 2021

(30) Foreign Application Priority Data
Jun. 8, 2020 (KR) 10-2020-0069200

(51) Int. Cl. C07F 7/22; G03F 7/004

(52) U.S. Cl. CPC C07F 7/2224; G03F 7/0048; G03F 7/0042

(57) ABSTRACT

Described herein are photoresist compositions comprising a metal structure including an organometallic compound, an organometallic nanoparticle, and/or an organometallic cluster; a C2 to C20 organic densifier including oxygen atoms; and a solvent. Also described herein are methods of using a photoresist composition.

### CROSS-REFERENCE TO RELATED APPLICATION

This application claims the benefit of and priority to Korean Patent Application No. 10-2020-0069200, filed on Jun. 8, 2020, in the Korean Intellectual Property Office, the disclosure of which is incorporated herein in its entirety by reference.

### FIELD

The inventive concept relates to a photoresist composition, and more particularly, to a photoresist composition containing a metal.

### BACKGROUND

In recent years, the downscaling of semiconductor devices has rapidly progressed due to the development of electronic technology. Thus, a photolithography process, which is advantageous in forming fine patterns, may be required. In particular, it would be advantageous to develop a photoresist composition that may increase a sensitivity and a critical dimension (CD) uniformity and improve line edge roughness (LER) characteristics while obtaining excellent etching resistance and resolution.

### SUMMARY

The inventive concept provides a photoresist composition. In some embodiments, a photoresist composition of the inventive concept obtains an excellent etching resistance and/or a high resolution, provides a uniform critical dimension (CD) distribution between wafers, and/or provides an improved sensitivity during a photolithography process for manufacturing an integrated circuit (IC) device.

According to an aspect of the inventive concept, provided is a photoresist composition comprising a metal structure including an organometallic compound, an organometallic nanoparticle, or an organometallic cluster; a C2 to C20 organic densifier including oxygen atoms; and a solvent.

According to another aspect of the inventive concept, provided is a photoresist composition comprising a metal structure including a metal core and an organic ligand that surrounds the metal core; a C2 to C20 organic densifier including a polyol; and an organic solvent.

According to another aspect of the inventive concept, provided is a photoresist composition comprising a metal structure including a metal element and an organic ligand that is bonded to the metal element, wherein the metal element is selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (Vc), chromium (Cr), cobalt (Co), nickel (Ni), copper (Cu), gallium (Ga), iron (Fe), and any combination thereof, a C2 to C20 organic densifier including at least two hydroxyl groups; and an organic solvent.

### BRIEF DESCRIPTION OF THE DRAWINGS

Embodiments of the inventive concept will be more clearly understood from the following detailed description taken in conjunction with the accompanying drawings.

FIGS. 1 to 5 are cross-sectional views illustrating a process sequence of a method of manufacturing an integrated circuit (IC) device according to some embodiments.

### DETAILED DESCRIPTION OF THE EMBODIMENTS

Hereinafter, embodiments will be described in detail with reference to the accompanying drawings. The same reference numerals are used to denote the same elements in the drawings, and repeated descriptions thereof will be omitted.

As used herein, “and/or” refers to and encompasses any and all possible combinations of one or more of the associated listed items, as well as the lack of combinations when interpreted in the alternative (“or”).

As used herein, the terms “increase,” “increasing,” “enhance,” “enhancing,” “improve” and “improving” (and grammatical variations thereof) describe an elevation of at least about 5%, 10%, 15%, 20%, 25%, 30%, 35%, 40%, 45%, 50%, 55%, 60%, 65%, 70%, 75%, 80%, 85%, 90%, 95%, 100%, 150%, 200%, 300%, 400%, 500% or more such as compared to another number (e.g., a control value).

As used herein, the terms “reduce,” “reduced,” “reducing,” “reduction,” “diminish,” and “decrease” (and grammatical variations thereof), describe, for example, a decrease of at least about 5%, 10%, 15%, 20%, 25%, 30%, 35%, 40%, 45%, 50%, 55%, 60%, 65%, 70%, 75%, 80%, 85%, 90%, 95%, 97%, 98%, 99%, or 100% such as compared to another number (e.g., a control value).

A photoresist composition according to some embodiments may include a metal structure including an organometallic compound, an organometallic nanoparticle, and/or an organometallic cluster; an organic densifier including an oxygen atom; and a solvent.

In example embodiments, the metal structure may include a metal core including at least one metal atom and at least one organic ligand surrounding the metal core. The at least one organic ligand may be bonded to the metal core. In the metal structure, there may be an ionic bond, a covalent bond, a metallic bond, and/or a van der Waals bond between the metal core and the organic ligand.

The metal core may include at least one metal element. The at least one metal element may have the form of a metal atom, a metal ion, a metal compound, a metal alloy, or any combination thereof. The metal compound may include a metal oxide, a metal nitride, a metal oxynitride, a metal silicide, a metal carbide, or any combination thereof. In example embodiments, the metal core may include at least one metal element selected from tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (Vc), chromium (Cr), cobalt (Co), nickel (Ni), copper (Cu), gallium (Ga), iron (Fe), and any combination thereof, but the inventive concept is not limited thereto.

In example embodiments, the organic ligand may include a C1 to C30 linear alkyl, C1 to C30 branched alkyl, C3 to C30 cycloalkyl, C2 to C30 alkenyl, C2 to C30 alkynyl, C6 to C30 aryl, C3 to C30 allyl, C1 to C30 alkoxy, C6 to C30 aryloxy, or any combination thereof. The organic ligand may include a hydrocarbyl group that is substituted with at least one hetero functional group including an oxygen atom, a nitrogen atom, a halogen element, cyano, thio, silyl, ether, carbonyl, ester, nitro, amino, or any combination thereof. The halogen element may be fluorine (F), chlorine (Cl), bromine (Br), and/or iodine (I).

For example, the organic ligand may include methyl, ethyl, propyl, butyl, isopropyl, tertiary butyl, tertiary amyl, secondary butyl, cyclopropyl, cyclobutyl, cyclopentyl, and/or cyclohexyl. The metal structure may include a plurality of organic ligands, and two of the plurality of organic ligands may form one cyclic alkyl moiety. The cyclic alkyl moiety may include 1-adamantyl or 2-adamantyl.

In example embodiments, the organic ligand may include an aromatic ring, a hetero aromatic ring, or any combination thereof.

In example embodiments, the organic ligand may include at least one selected from the following structural units, wherein “*” denotes a bonding position between the organic ligand and a metal element included in the metal core:

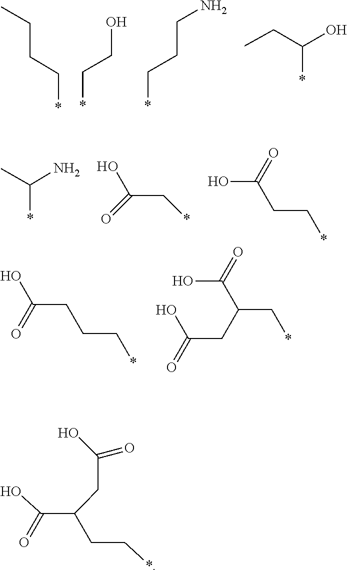

In other example embodiments, the organic ligand may include at least one selected from the following structural units, wherein “*” denotes a bonding position between the organic ligand and a metal element included in the metal core:

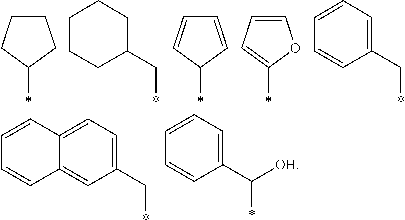

In yet other example embodiments, the organic ligand may include at least one selected from the following structural units:

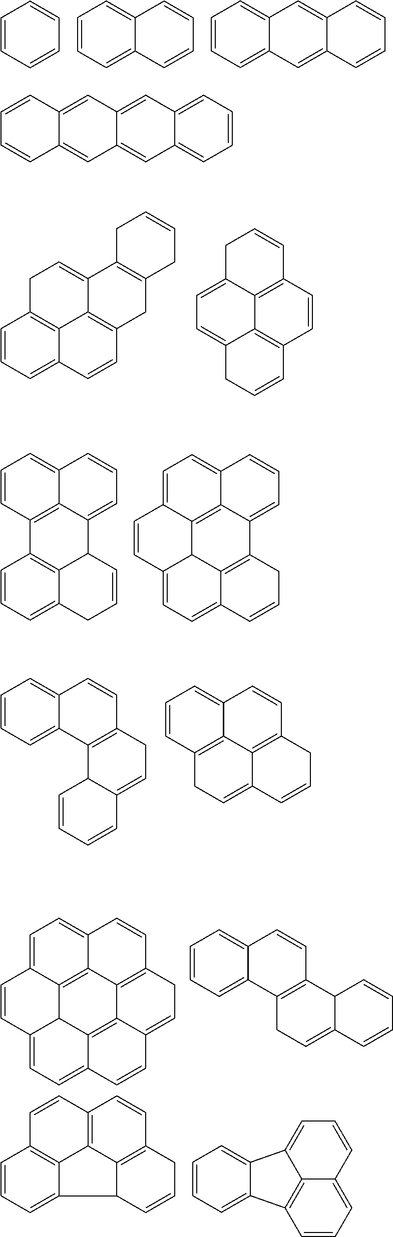

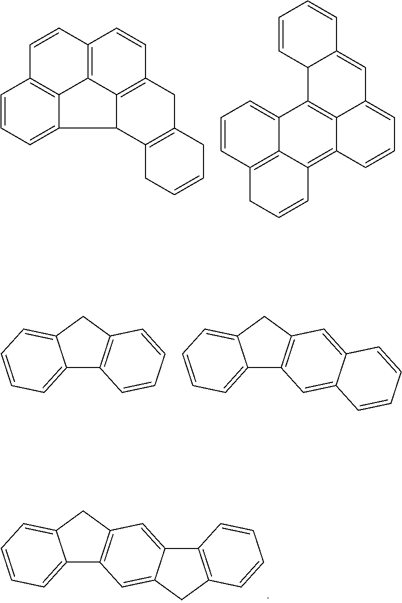

In example embodiments, the metal structure may include (tBu)Sn(NEt₂)₂(OtBu), (tBu)Sn(NEt₂)(NH₂)(OtBu), (tBu)Sn(NEt₂)(OtBu)₂, (Me)Sn(NEt₂)(OtBu)₂, (Me)Sn(NEt₂)₂(OtBu), (tBu)₂Sn(NEt₂)(OtBu), (Me)₂Sn(NEt₂)(OtBu), (Me)(tBu)Sn(NEt₂)₂, (Me)(tBu)Sn(NEt₂)(OtBu), (iPr)(tBu)Sn(NMe₂)(OtBu), or any combination thereof, wherein “Me” refers to a methyl group, “Et” refers to an ethyl group, and “tBu” refers to a tert-butyl group.

In other example embodiments, the metal structure may include at least one compound selected from the following Formulas 1 to 7:

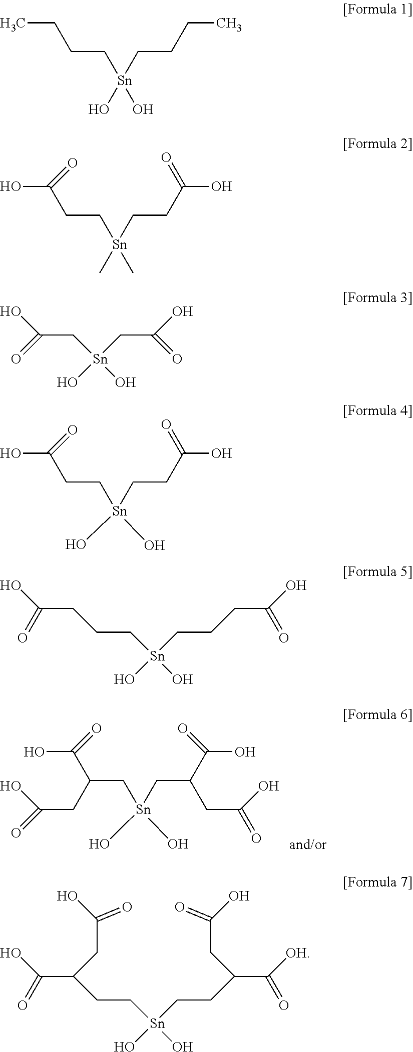

In the photoresist composition according to the embodiments, the metal structure may be present in an amount of about 0.1% to about 99% by weight, based on the total weight of the photoresist composition. When a content of the metal structure is excessively low or high in the photoresist composition, the storage stability of the photoresist composition may be degraded, and the ability to form the photoresist film using the photoresist composition may be reduced.

In the photoresist composition according to the embodiments, the organic densifier may increase a difference in solubility in the developer between an exposed area and a non-exposed area of the photoresist film when a photoresist pattern is formed by exposing and developing the photoresist film obtained from the photoresist composition. In some embodiments, the solubility of an exposed area in a developer may be reduced compared to and/or lower than the solubility of a non-exposed area in the developer.

In example embodiments, the organic densifier may be represented by the following General formula 1:

R(OH)ₘ, [General formula 1]
wherein R is a C2 to C20 m-valent organic group having 0 or one hydroxyl group, and m is an integer ranging from 2 to 4.

In example embodiments, R of General formula 1 may be a C2 to C10 organic group.

In example embodiments, R of General formula 1 may include an oxygen atom, a nitrogen atom, a sulfur atom, a phosphorus atom, and/or a halogen element. The halogen element may be selected from F, Cl, Br, and/or I.

In example embodiments, R of General formula 1 may include a carbon-carbon double bond and/or a carbon-carbon triple bond.

In example embodiments, R of General formula 1 may include an ether group, a carbonyl group, and/or an imine group.

In example embodiments, the organic densifier may include an acid group selected from a hydroxyl group, a sulfonate group, a carboxyl group, and/or a phosphonate group.

In example embodiments, the organic densifier may include a polyol including at least two hydroxyl groups. For example, the organic densifier may include diol, triol, tetraol, and/or pentaol.

In example embodiments, the organic densifier may include alkylenediol, polyetherdiol, glycerol, 2-(hydroxymethyl)-1,3-propanediol, 1,3-dihydroxypropan-2-yl dihydrogen phosphate, or any combination thereof.

The alkylenediol may be linear alkylenediol or branched alkylenediol. Examples of the linear alkylenediol may include ethylene glycol, 1,3-propylene glycol, 1,4-butanediol, 1,5-pentanediol, 1,6-hexanediol, 1,7-heptanediol, 1,8-octanediol, 1,9-nonanediol, 1,10-decanediol, and/or the like. Examples of the branched alkylenediol may include neopentylglycol, 2,4-diethyl-1,5-pentanediol, 2,4-dibutyl-1,5-pentanediol, 3-methyl-1,5-pentanediol, 1-methylethylene glycol, 1-ethylethylene glycol, and/or the like.

Examples of polyetherdiol may include diethylene glycol, triethylene glycol, tetraethylene glycol, dipropylene glycol, tripropylene glycol, and/or the like.

In example embodiments, the organic densifier may include triol. Specific examples of the organic densifier including triol may include glycerol, 1,1,1-tris(hydroxymethyl)ethane, 2-hydroxymethyl-1,3-propanediol, 2-ethyl-2-(hydroxymethyl)-1,3-propanediol, 2-hydroxymethyl-2-propyl-1,3-propanediol, 2-hydroxymethyl-1,4-butanediol, 2-hydroxyethyl-2-methyl-1,4-butanediol, 2-hydroxymethyl-2-propyl-1,4-butanediol, 2-ethyl-2-hydroxyethyl-1,4-butanediol, 1,2,3-butanetriol, 1,2,4-butanetriol, 3-(hydroxymethyl)-3-methyl-1,4-pentanediol, 1,2,5-pentanetriol, 1,3,5-pentanetriol, 1,2,3-trihydroxyhexane, 1,2,6-trihydroxyhexane, 2,5-dimethyl-1,2,6-hexanetriol, tris(hydroxymethyl)nitromethane, 2-methyl-2-nitro-1,3-propanediol, 2-bromo-2-nitro-1,3-propanediol, 1,2,4-cyclopentanetriol, 1,2,3-cyclopentanetriol, 1,3,5-cyclohexanetriol, 1,3,5-cyclohexanetrimethanol, and/or the like.

In example embodiments, the organic densifier may include tetraol. Specific examples of the organic densifier including tetraol may include butane-1,2,3,4-tetrol(butane-1,2,3,4-tetrol), 2,2-bis(hydroxymethyl)-1,3-propanediol, pentane-1,2,4,5-tetrol, and/or the like.

In example embodiments, the organic densifier may include, but the inventive concept is not limited thereto, at least one selected from the following compounds:

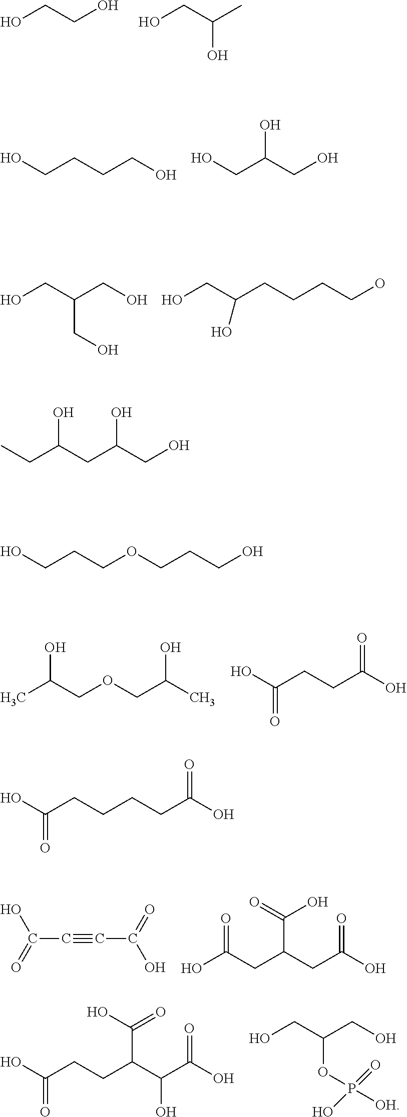

The organic densifier may be present in an amount of about 0.1% to about 30% by weight, based on the total weight of the photoresist composition. When a content of the organic densifier in the photoresist composition is excessively low, the organic densifier may not sufficiently increase the difference in solubility in the developer between the exposed area and the non-exposed area of the photoresist film. When a content of the organic densifier in the photoresist composition is excessively high, the ability to form the photoresist film using the photoresist composition may be reduced.

The solvent present in the photoresist composition may include an organic solvent. The organic solvent may include at least one of ether, alcohol, glycolether, an aromatic hydrocarbon compound, ketone, and/or ester, without being limited thereto. For example, the organic solvent may include ethylene glycol monomethylether, ethylene glycol monoethylether, methylcellosolve acetate, ethylcellosolve acetate, diethylene glycolmethylether, diethylene glycolethylether, propylene glycol, propylene glycolmethylether (PGME), propylene glycolmethylether acetate (PGMEA), propylene glycolethylether, propylene glycolethylether acetate, propylene glycolpropylether acetate, propylene glycolbutylether, propylene glycolbutylether acetate, ethanol, propanol, isopropyl alcohol, isobutyl alcohol, 4-methyl-2-pentanol (or methyl isobutyl carbinol (MIBC)), hexanol, 1-methoxy-2-propanol, 1-ethoxy-2-propanol, ethylene glycol, propylene glycol, heptanone, propylene carbonate, butylene carbonate, toluene, xylene, methylethylketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or any combination thereof.

In the photoresist composition according to the embodiments, the solvent may be present in an amount that makes up the remaining percentage of the composition excluding the amounts of other components including the metal structure and the organic densifier. In example embodiments, the solvent may be present in an amount of about 0.1% to about 99.8% by weight, based on the total weight of the photoresist composition.

In example embodiments, the photoresist composition according to embodiments may further include at least one selected from a surfactant, a dispersant, a desiccant, and/or a coupling agent.

The surfactant may improve the coating uniformity and/or wettability of the photoresist composition. In example embodiments, the surfactant may include sulfuric acid ester salts, sulfonates, phosphate ester, soap, amine salts, quaternary ammonium salts, polyethylene glycol, alkylphenol ethylene oxide adducts, polyols, a nitrogen-containing vinyl polymer, or any combination thereof, without being limited thereto. For example, the surfactant may include alkylbenzene sulfonates, alkylpyridinium salts, polyethylene glycol, and/or quaternary ammonium salts. When the photoresist composition includes the surfactant, the surfactant may be present in an amount of about 0.001% to about 3% by weight, based on the total weight of the photoresist composition.

The dispersant may uniformly disperse respective components in the photoresist composition. In example embodiments, the dispersant may include an epoxy resin, polyvinyl alcohol, polyvinyl butyral, polyvinylpyrrolidone, glucose, sodium dodecyl sulfate, sodium citrate, oleic acid, linoleic acid, or any combination thereof, without being limited thereto. When the photoresist composition includes the dispersant, the dispersant may be present in an amount of about 0.001% to about 5% by weight, based on the total weight of the photoresist composition.

The desiccant may prevent adverse effects due to moisture in the photoresist composition. For example, the desiccant may prevent a metal present in the photoresist composition from being oxidized due to moisture. In example embodiments, the desiccant may include polyoxyethylene nonylphenolether, polyethylene glycol, polypropylene glycol, polyacrylamide, or any combination thereof, without being limited thereto. When the photoresist composition includes the desiccant, the desiccant may be present in an amount of about 0.001% to about 10% by weight, based on the total weight of the photoresist composition.

The coupling agent may increase adhesion of the photoresist composition with a lower film when the lower film is coated with the photoresist composition. In example embodiments, the coupling agent may include a silane coupling agent. The silane coupling agent may include vinyl trimethoxysilane, vinyl triethoxysilane, vinyl trichlorosilane, vinyl tris(P-methoxyethoxy)silane, 3-methacryl oxypropyl trimethoxysilane, 3-acryl oxypropyl trimethoxysilane, p-styryl trimethoxysilane, 3-methacryl oxypropyl methyldimethoxysilane, 3-methacryl oxypropyl methyldiethoxysilane, and/or trimethoxy[3-(phenylamino)propyl]silane, without being limited thereto. When the photoresist composition includes the coupling agent, the coupling agent may be present in an amount of 0.001% to about 5% by weight, based on the total weight of the photoresist composition.

In the photoresist composition according to some embodiments, when the solvent includes only the organic solvent, the photoresist composition may further include water. In this case, water may be present in an amount of about 0.001% to about 0.1% by weight, in the photoresist composition.

The photoresist composition according to example embodiments may include a metal structure and an organic densifier including oxygen atoms. Accordingly, during a photolithography process using the photoresist composition, after the photoresist film obtained from the photoresist composition is exposed, a crosslinking reaction between the metal structures may efficiently occur due to the oxygen atoms included in the organic densifier. Thus, a network of metals included in the metal structures may be densely formed in the exposed area of the photoresist film. As a result, the network of the metals may become denser in the exposed area of the photoresist film than in the non-exposed area, and thus, a difference in solubility in the developer between the exposed area and the non-exposed area of the photoresist film may be increased. When an integrated circuit (IC) device is manufactured using a photoresist composition according to embodiments of the inventive concept, an excellent resolution and/or improved sensitivity may be provided in a photolithography process, and/or a photoresist film formed using the photoresist composition may obtain an etching resistance. Accordingly, patterns having a desired shape required for an IC device may be easily formed and/or a critical dimension (CD) distribution of the patterns may be uniformly controlled.

A photoresist composition according to some embodiments may be advantageously used to form a pattern having a relatively high aspect ratio. For example, a photoresist composition according to some embodiments may be advantageously used in a photolithography process for forming a pattern having a fine width in a range of about 5 nm to about 100 nm.

Next, a method of manufacturing an IC device using a photoresist composition according to embodiments of the inventive concept will be described with reference to a specific example.

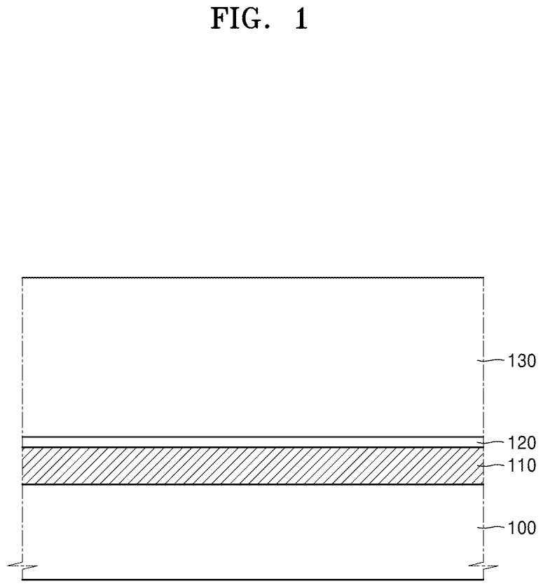

FIGS. 1 to 5 are cross-sectional views illustrating a process sequence of a method of manufacturing an IC device, according to some embodiments.

Referring to FIG. 1, a feature layer 110 may be formed on a substrate 100, and a photoresist film 130 may be formed on the feature layer 110 using a photoresist composition according to an embodiment. The photoresist film 130 may include a metal structure and an organic densifier including oxygen atoms, each of which are components of the photoresist composition. A detailed structure of the photoresist composition is as described above.

The substrate 100 may include a semiconductor substrate. The feature layer 110 may include an insulating film, a conductive film, and/or a semiconductor film. For example, the feature layer 110 may include a metal, an alloy, a metal carbide, a metal nitride, a metal oxynitride, a metal oxycarbide, a semiconductor, polysilicon, oxide, nitride, oxynitride, or any combination thereof, without being limited thereto.

In example embodiments, before the photoresist film 130 is formed on the feature layer 110, a developable bottom anti-reflective coating (DBARC) film 120 may be formed on the feature layer 110. In this case, the photoresist film 130 may be formed on the DBARC film 120. The DBARC film 120 may control the diffused reflection of light from a light source used in an exposure process for manufacturing an IC device and/or absorb light reflected by the feature layer 110 formed thereunder. In example embodiments, the DBARC film 120 may include an organic anti-reflective coating (ARC) material for a krypton fluoride (KrF) excimer laser, an argon fluoride (ArF) excimer laser, or any other light source. In example embodiments, the DBARC film 120 may include an organic component having a light absorption structure. The light absorption structure may include, for example, a hydrocarbon compound in which at least one benzene ring is fused. The DBARC film 120 may be formed to and/or have a thickness of about 20 nm to about 100 nm, without being limited thereto.

To form the photoresist film 130, the DBARC film 120 may be coated with a photoresist composition according to an embodiment of the inventive concept, and the photoresist composition may be annealed. The coating process may be performed using a method, such as a spin coating process, a spray coating process, and/or a deep coating process. The process of annealing the photoresist composition may be performed at a temperature of about 80° C. to about 300° C. for about 10 seconds to about 100 seconds, without being limited thereto. A thickness of the photoresist film 130 may be several tens of times to several hundreds of times a thickness of the DBARC film 120. In some embodiments, the photoresist film 130 may be formed to and/or have a thickness of about 100 nm to about 6 m, without being limited thereto.

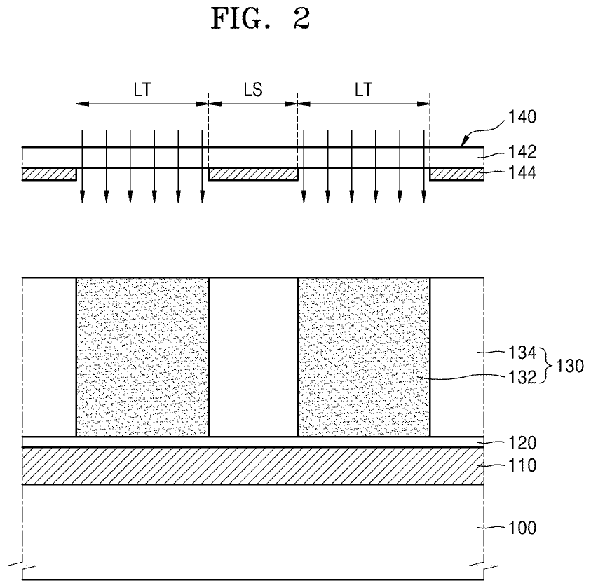

Referring to FIG. 2, a first area 132, which is a portion of the photoresist film 130, may be exposed.

During the exposure of the photoresist film 130, metal atoms in the first area 132 of the photoresist film 130 may be crosslinked at a relatively high density by the organic densifier, and thus, a network of metal structures may be densely formed. Accordingly, a difference in solubility in a developer between the first area 132 of the photoresist film 130, which is exposed, and a second area 134 of the photoresist film 130, which is not exposed, may be increased. In some embodiments, the solubility of the first area 132 in a developer is lower than the solubility of the second area 134 in the developer.

The photoresist film 130 may be obtained from the photoresist composition according to the inventive concept. The photoresist composition may include an organic densifier including a hydroxyl group or an acid group including oxygen atoms. In some embodiments, by appropriately selecting compound structures included in the organic densifier, a length of a link between the metal atoms due to the organic densifier may be variously controlled in the network of the metal structures formed in the first area 132. Accordingly, a crosslinking density in the network of metal structures formed in the first area 132 of the photoresist film 130 may be variously adjusted according to embodiments of the inventive concept.

According to the inventive concept, a metal structure included in the photoresist composition that is used to form the photoresist film 130 may not need to include a bulky organic ligand, which may cause steric hindrance during the formation of the network. When the metal structure includes a bulky organic ligand that causes steric hindrance, the efficiency of a crosslinking reaction between the metal structures may be reduced during exposure of the photoresist film 130. Thus, it may be difficult to obtain a pattern having a high pattern fidelity in the photoresist pattern. However, according to the inventive concept, during the formation of the network, the crosslinking density between the metal structures may be effectively increased during the step of exposing of the photoresist film 130 by applying the organic densifier including the oxygen atoms to the photoresist composition. This may be accomplished since the inventive concept may not utilize (e.g., may be devoid of) a metal structure including the bulky organic ligand, which can cause steric hindrance. As a result, a high pattern fidelity may be achieved according to embodiments of the inventive concept such as by reducing a line edge roughness (LER) and/or a line width roughness (LWR) in the photoresist pattern.

To expose the first area 132 of the photoresist film 130, a photomask 140 having a plurality of light-shielding areas LS and a plurality of light-transmitting areas LT may be arranged at a predetermined position on the photoresist film 130, and the first area 132 of the photoresist film 130 may be exposed through the plurality of light-transmitting areas LT of the photomask 140. The first area 132 of the photoresist film 130 may be exposed using a KrF excimer laser (248 nm), an ArF excimer laser (193 nm), an F₂ excimer laser (157 nm), and/or an extreme ultraviolet (EUV) laser (13.5 nm).

The photomask 140 may include a transparent substrate 142 and a plurality of light-shielding patterns 144 formed on the transparent substrate 142 in the plurality of light-shielding areas LS. The transparent substrate 142 may include quartz. The plurality of light-shielding patterns 144 may include chromium (Cr). The plurality of light-transmitting areas LT may be defined by the plurality of light-shielding patterns 144. According to the inventive concept, a reflective photomask (not shown) for an EUV exposure process may be used instead of the photomask 140 to expose the first area 132 of the photoresist film 130.

After the first area 132 of the photoresist film 130 is exposed, the photoresist film 130 may be annealed. The annealing process may be performed at a temperature of about 50° C. to about 200° C. for about 10 seconds to about 100 seconds, without being limited thereto. In example embodiments, the network of the metal structures may be further densified by the organic densifier during the annealing of the photoresist film 130. Thus, in the photoresist film 130, a difference in solubility in the developer between the first area 132, which is exposed, and the second area 134, which is not exposed, may be further increased. Accordingly, a high pattern fidelity may be obtained by reducing an LER and/or an LWR in a final pattern to be formed in the feature layer 110 during a subsequent process.

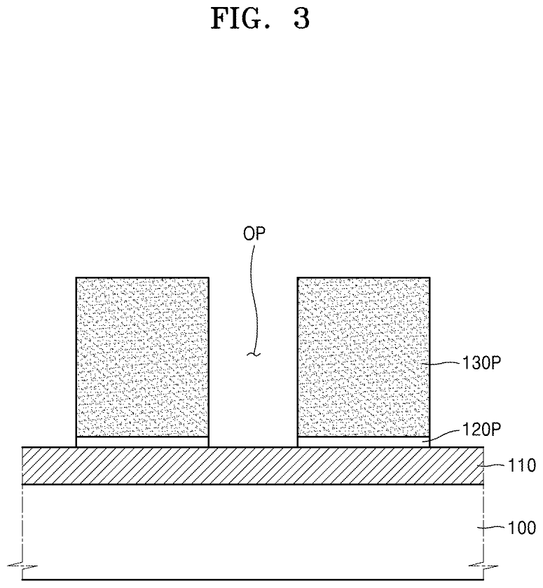

Referring to FIG. 3, a photoresist pattern 130P may be formed by developing the photoresist film 130 that has been exposed.

In example embodiments, the photoresist film 130, which is exposed, shown in FIG. 2, may be developed to remove the second area 134 of the photoresist film 130, which is not exposed, and the photoresist pattern 130P including the first area 132 of the photoresist film 130, which is exposed, may be formed. The photoresist pattern 130P may include a plurality of openings OP. Portions of the DBARC film 120, which are exposed through the plurality of openings OP, may be removed to form a DBARC pattern 120P.

In example embodiments, developing of the photoresist film 130 may be performed using a negative-tone development (NTD) process. In this case, normal-butyl acetate (or n-butyl acetate) and/or 2-heptanone may be used as the developer, but the type of the developer is not limited thereto.

In other example embodiments, unlike the illustration of FIG. 3, the photoresist film 130, which is exposed, may be developed using a positive-tone development (PTD) process, and thus, a photoresist pattern (not shown) including a non-exposed area of the photoresist film 130 may be formed.

In example embodiments, various developers may be used to develop the photoresist film 130 that has been exposed. For example, 2-octanone, 2-nonanone, 2-heptanone, 3-heptanone, 4-heptanone, 2-hexanone, 3-hexanone, diisobutyl ketone, methylcyclohexanone, acetophenone, methyl acetophenone, propyl acetate, butyl acetate, isobutyl acetate, amyl acetate, butenyl acetate, isoamyl acetate, phenyl acetate, propyl formate, butyl formate, isobutyl formate, amyl formate, isoamyl formate, methyl valerate, methyl pentenate, methyl crotonate, ethyl crotonate, methyl propionate, ethyl propionate, 3-ethoxyethyl propionate, methyl lactate, ethyl lactate, propyl lactate, butyl lactate, isobutyl lactate, amyl lactate, isoamyl lactate, 2-hydroxymethyl isobutyrate, 2-hydroxy ethyl-2-hydroxy isobutyrate, methyl benzoate, ethyl benzoate, phenyl acetate, benzyl acetate, phenylmethyl acetate, benzyl formate, phenylethyl formate, methyl-3-phenylpropionate, benzyl propionate, ethyl phenyl acetate, 2-phenylethyl acetate, or any combination thereof may be used as the developer, but the inventive concept is not limited thereto.

In the photoresist film 130 shown in FIG. 2, a dense network of metal structures may be formed by the organic densifier in the first area 132, which is exposed, and thus, a difference in solubility in the developer between the first area 132, which is exposed, and the second area 134, which is not exposed, may be increased. Thus, in developing the photoresist film 130 that has been exposed, the first area 132 may not be removed but may remain as it is while the second area 134 is removed by developing the photoresist film 130. Accordingly, after the photoresist film 130 is developed, the photoresist pattern 130P may obtain vertical sidewall profiles without causing residual defects, such as a footing phenomenon. By improving profiles of the photoresist pattern 130P as described above, when the feature layer 110 is processed using the photoresist pattern 130P, CDs of processing regions that are intended in the feature layer 110 may be precisely controlled.

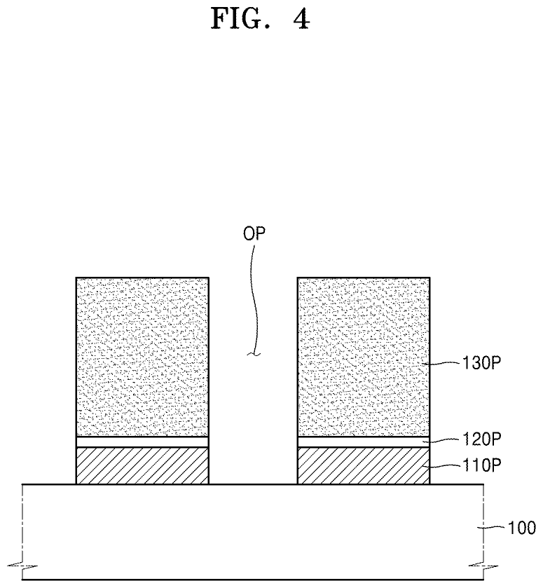

Referring to FIG. 4, the feature layer 110 may be processed using the photoresist pattern 130P in the resultant structure of FIG. 3.

For example, to process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, and/or a process of modifying portions of the feature layer 110 through the openings OP may be performed. FIG. 4 illustrates a process of forming a feature pattern 110P by etching the feature layer 110 that is exposed by the openings OP as an example of processing the feature layer 110.

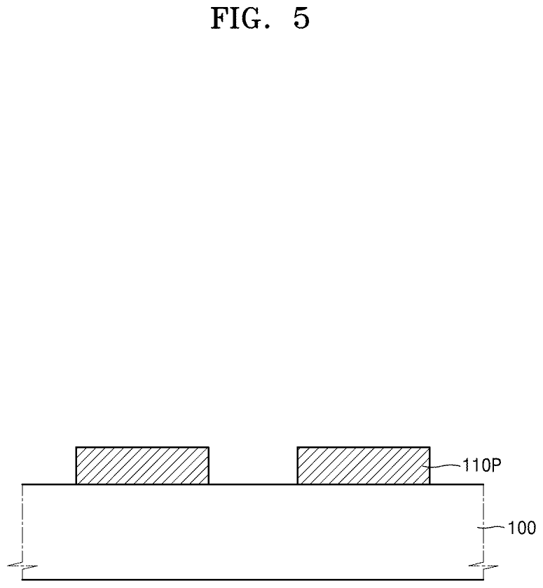

Referring to FIG. 5, the photoresist pattern 130P and the DBARC pattern 120P remaining on the feature pattern 110P may be removed from the resultant structure of FIG. 4. The photoresist pattern 130P and the DBARC pattern 120P may be removed using an ashing process and a strip process.

In the method of manufacturing an IC device according to some embodiments, which has been described with reference to FIGS. 1 to 5, a difference in solubility in the developer between the exposed area 132 and the non-exposed area 134 may be increased in a photoresist film 130 obtained using a photoresist composition according to the inventive concept. Thus, a high pattern fidelity may be achieved by reducing an LER and/or an LWR in the photoresist pattern 130P obtained from the photoresist film 130. Accordingly, when a subsequent process is performed on a feature layer 110 using the photoresist pattern 130P, a dimensional accuracy may be increased by precisely controlling CDs of processing regions and/or patterns to be formed in the feature layer 110. In addition, a CD distribution of the feature pattern 110P on the substrate 100 may be uniformly controlled and/or the productivity of a method of manufacturing an IC device may be improved. In some embodiments, a photoresist composition and/or method of the inventive concept may improve inter-point critical dimension uniformity (IPU), local CD uniformity (LCDU), and/or LER compared to IPU, LCDU, and/or LER that is achieved in a manner devoid of a photoresist composition and/or method of the inventive concept.

While the inventive concept has been particularly shown and described with reference to embodiments thereof, it will be understood that various changes in form and details may be made therein without departing from the spirit and scope of the following claims.

What is claimed is:

1. A photoresist composition comprising:
a metal structure comprising an organometallic compound, an organometallic nanoparticle, or an organometallic cluster;
an organic densifier comprising a C2 to C20 organic group comprising oxygen atoms; and
a solvent.

2. The photoresist composition of claim 1, wherein the organic densifier comprises a polyol comprising at least two hydroxyl groups.

3. The photoresist composition of claim 1, wherein the organic densifier comprises an ether group, a carbonyl group, or an imine group.

4. The photoresist composition of claim 1, wherein the organic densifier comprises a hydroxyl group, a sulfonate group, a carboxyl group, or a phosphonate group.

5. The photoresist composition of claim 1, wherein the metal structure comprises a metal core that includes at least one metal atom and at least one organic ligand that surrounds the metal core.

6. The photoresist composition of claim 1, wherein the metal structure comprises tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (Vc), chromium (Cr), cobalt (Co), nickel (Ni), copper (Cu), gallium (Ga), iron (Fe), or any combination thereof.

7. The photoresist composition of claim 1, wherein the metal structure comprises a metal core and an organic ligand surrounding the metal core, and
wherein the organic ligand comprises a C1 to C30 linear alkyl, a C1 to C30 branched alkyl, a C3 to C30 cycloalkyl, a C2 to C30 alkenyl, a C2 to C30 alkynyl, a C6 to C30 aryl, a C3 to C30 allyl, a C1 to C30 alkoxy, a C6 to C30 aryloxy, or any combination thereof.

8. The photoresist composition of claim 1, wherein the metal structure comprises a metal core and an organic ligand surrounding the metal core, and
wherein the organic ligand comprises a hydrocarbyl group that is substituted with at least one heteroatom functional group comprising an oxygen atom, a nitrogen atom, a halogen atom, cyano, thio, silyl, ether, carbonyl, ester, nitro, amino, or any combination thereof.

9. The photoresist composition of claim 1, further comprising a surfactant, a dispersant, a desiccant, and/or a coupling agent.

10. A photoresist composition comprising:
a metal structure comprising a metal core and an organic ligand that surrounds the metal core;
an organic densifier comprising a C2 to C20 polyol; and
an organic solvent.

11. The photoresist composition of claim 10, wherein the metal core comprises tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (Vc), chromium (Cr), cobalt (Co), nickel (Ni), copper (Cu), gallium (Ga), iron (Fe), or any combination thereof.

12. The photoresist composition of claim 10, wherein the organic densifier has a structure of General formula 1:
R(OH)ₘ, [General formula 1]
wherein R is a C2 to C20 m-valent organic group having 0 or one hydroxyl group, and m is an integer of 2 to 4.

13. The photoresist composition of claim 12, wherein R comprises an oxygen atom, a nitrogen atom, a sulfur atom, a phosphorus atom, or a halogen element.

14. The photoresist composition of claim 10, wherein the organic densifier comprises a linear alkylene diol, a branched alkylene diol, or a polyether diol.

15. The photoresist composition of claim 10, further comprising a surfactant, a dispersant, a desiccant, and/or a coupling agent.

16. The photoresist composition of claim 10, wherein the metal structure is present in an amount of 0.1% to 99% by weight, based on a total weight of the photoresist composition, and
the organic densifier is present in an amount of 0.1% to 30% by weight, based on the total weight of the photoresist composition.

17. A photoresist composition comprising:
a metal structure comprising a metal element and an organic ligand that is bound to the metal element, wherein the metal element comprises tin (Sn), antimony (Sb), indium (In), bismuth (Bi), silver (Ag), tellurium (Te), gold (Au), lead (Pb), zinc (Zn), titanium (Ti), hafnium (Hf), zirconium (Zr), aluminum (Al), vanadium (Vc), chromium (Cr), cobalt (Co), nickel (Ni), copper (Cu), gallium (Ga), iron (Fe), or any combination thereof;
an organic densifier comprising a C2 to C20 organic group including at least two hydroxyl groups; and
an organic solvent.

18. The photoresist composition of claim 17, wherein the organic densifier comprises one or more of the following compounds:

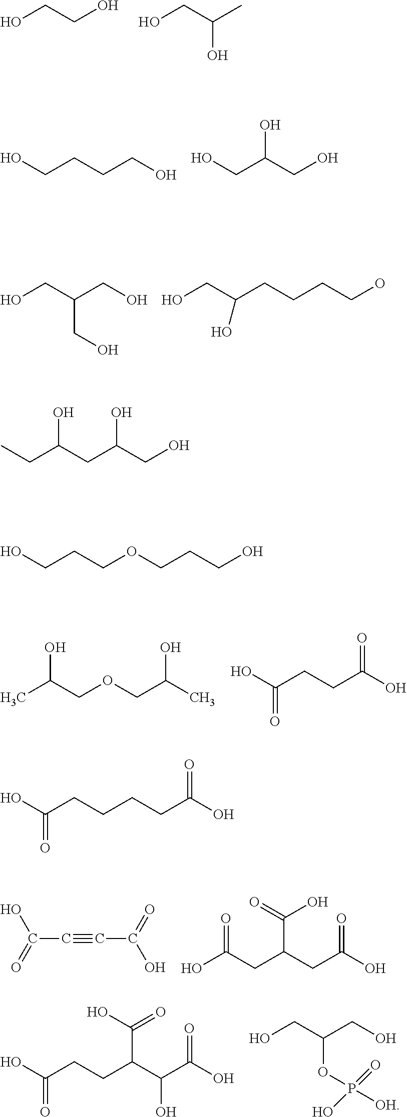

19. The photoresist composition of claim 17, wherein the organic ligand comprises one or more of the following structures: 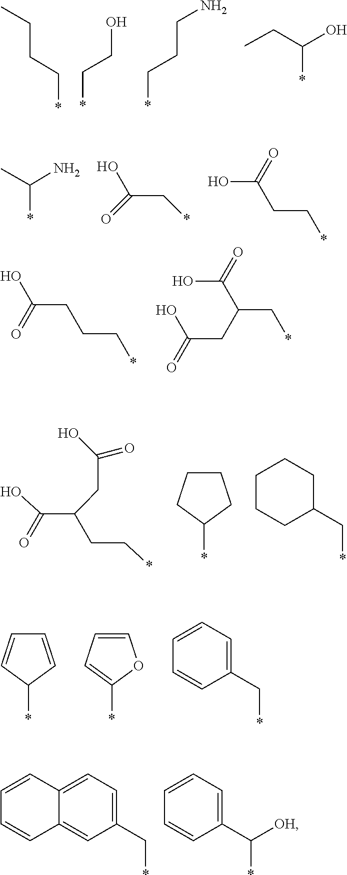
wherein “*” denotes a bonding position between the organic ligand and the metal element.

20. The photoresist composition of claim 17, wherein the metal structure is present in an amount of 0.1% to 99% by weight, based on a total weight of the photoresist composition, and
the organic densifier is present in an amount of 0.1% to 30% by weight, based on the total weight of the photoresist composition.
